(19) United States
(12) Patent Application Publication
(10) Pub. No.: US 2026/0354111 A1
(43) Pub. Date: Nov. 5, 2026

(54) LIFT PIN CONSTRUCTIONS FOR SEMICONDUCTOR FABRICATION PROCESSING WITH CONTACTS

(71) Applicant: ASM IP Holding B.V., Almere (NL)

(72) Inventors: Hang Zhang, Tempe, AZ (US); Kyle Tantiwong, Scottsdale, AZ (US); Todd Robert Dunn, Cave Creek, AZ (US)

(21) Appl. No.: 19/661,828

(22) Filed: Apr. 29, 2026

Related U.S. Application Data
(60) Provisional application No. 63/798,848, filed on May 2, 2025.

(51) Int. Cl. H10P 72/76

(52) U.S. Cl. CPC H10P 72/7612

(57) ABSTRACT

In accordance with examples of the disclosure one example includes an apparatus including a susceptor disposed within an interior space of a reaction chamber. The susceptor includes a plurality of through-holes in an axial direction. The apparatus further includes one or more lift pins slidably disposed in the respective through-holes. The apparatus further includes a weight element disposed along an end of the lift pin. The weight element is removably retained on the lift pin by a retaining element. The apparatus further includes one or more pin pads disposed below the susceptor. Each pin pad is aligned with one lift pin from the plurality of lift pins and includes one or more contacts that are in contact with the weight element.

### CROSS-REFERENCE TO RELATED APPLICATIONS

This application is a nonprovisional of, and claims priority to and the benefit of, U.S. Provisional Patent Application No. 63/798,848, filed May 2, 2025 and entitled “LIFT PIN CONSTRUCTIONS FOR SEMICONDUCTOR FABRICATION PROCESSING WITH CONTACTS,” which is incorporated by reference herein.

### FIELD

Lift pin pad constructions as disclosed herein relate to lift pin pads as used for semiconductor fabrication processing and, more specifically, to lift pin pad constructions specially configured to facilitate ease of assembly in a reactor used for semiconductor fabrication processing and promote reliable use during such semiconductor fabrication processing.

### BACKGROUND

Conventionally, lift pins, may be used in semiconductor fabrication processing to contact and/or guide a substrate placement (e.g., relative upward and downward movement, of the substrate) onto a susceptor disposed in a reaction chamber for subsequent semiconductor processing, such as atomic layer deposition of materials, chemical treatment, or the like. Lift pins may be moved downwardly relative to the susceptor by gravity, e.g., using a weight of the lift pin itself.

During such placement, friction may occur between the lift pin and a pin pad, resulting in chipping of the pin pad, material transfer, and breakage of the pin. This happens as the susceptor exerts pressure on the tilted lift pin, causing it to rub against the pin pad. Over time, the frictional force during the susceptor's cyclical movement up and down degrades the contact surface between the bottom of the pin and the pad.

It is, therefore, desired that a lift pin for use in semiconductor fabrication processing be specifically constructed in a manner that avoids the above-described issues.

Any discussion, including discussion of problems and solutions set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

In accordance with examples of the disclosure one example includes an apparatus including a susceptor disposed within an interior space of a reaction chamber. The susceptor includes a plurality of through-holes in an axial direction. The apparatus further includes one or more lift pins slidably disposed in the respective through-holes. The apparatus further includes a weight element disposed along an end of the lift pin. The weight element is removably retained on the lift pin by a retaining element. The apparatus further includes one or more pin pads disposed below the susceptor. Each pin pad is aligned with one lift pin from the plurality of lift pins and includes one or more contacts that contact the weight element.

In accordance with examples of the disclosure another example includes an apparatus including a susceptor disposed within an interior space of a reaction chamber. The susceptor includes a plurality of through-holes in an axial direction. The apparatus further includes one or more lift pins slidably disposed in the respective through-holes. The apparatus further includes a weight element disposed along an end of the lift pin. The weight element is removably retained on the lift pin by a retaining element. The apparatus further includes one or more pin pads disposed below the susceptor. Each pin pad is aligned with one lift pin from the plurality of lift pins. Each weight element comprises one or more contacts that contact the lift pins.

In accordance with examples of the disclosure one example includes an apparatus including a susceptor disposed within an interior space of a reaction chamber. The susceptor includes a plurality of through-holes in an axial direction. The apparatus further includes one or more lift pins slidably disposed in the respective through-holes. The apparatus further includes a weight element disposed along an end of the lift pin. The weight element is removably retained on the lift pin by a retaining element. The apparatus further includes one or more pin pads disposed below the susceptor. Each pin pad is aligned with one lift pin from the plurality of lift pins. Each lift pin comprises one or more contacts that contact the weight element.

For purposes of summarizing the invention and the advantages achieved over the prior art, certain objects and advantages of the invention have been described herein above. Of course, it is to be understood that not necessarily all such objects or advantages may be achieved in accordance with any particular example of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these examples are intended to be within the scope of the invention herein disclosed. These and other examples will become readily apparent to those skilled in the art from the following detailed description of certain examples having reference to the attached figures, the invention not being limited to any particular example(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the examples of the present disclosure may be derived by referring to the detailed description and claims when considered in connection with the following illustrative figures.

These and other features and advantages of lift pin constructions used for semiconductor fabrication processing as disclosed herein will be appreciated as the same becomes better understood by reference to the following detailed description when considered in connection with the accompanying drawings where

FIG. 1A is a schematic cross-sectional view of an example lift pin construction as disclosed herein in a first position for use in semiconductor fabrication processing;

FIG. 1B is a schematic cross-sectional view of the example lift pin construction of FIG. 1A in a second position;

FIG. 2A is a cross-sectional view of a section of the example lift pin construction of FIGS. 1A and 1B with contacts on the pin pad;

FIG. 2B are top views of a section of the example lift pin construction of FIGS. 1A and 1B with contacts on the pin pad;

FIG. 3 illustrates a lift pin axis analysis; and

FIG. 4 is a schematic cross-sectional view of another example lift pin construction as disclosed herein with contacts on the weight element.

It will be appreciated that elements in the figures are illustrated for simplicity and clarity and have not necessarily been drawn to scale. For example, the dimensions of some of the elements in the figures may be exaggerated relative to other elements to help improve understanding of illustrated examples of the present disclosure.

### DETAILED DESCRIPTION

The description of exemplary examples of methods and compositions provided below is merely exemplary and is intended for purposes of illustration only. The following description is not intended to limit the scope of the disclosure or the claims. Moreover, recitation of multiple examples having indicated features or steps is not intended to exclude other examples having additional features or steps or other examples incorporating different combinations of the stated features or steps.

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

The illustrations presented herein are not meant to be actual views of any particular material, apparatus, structure, or device, but are merely representations that are used to describe examples of the disclosure.

As used herein, the term “substrate” can refer to any underlying material or materials that may be used, or upon which, a device, a circuit, or a film/layer may be formed.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes but still be at least partially continuous. In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some examples. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples. In some cases, percentages indicate herein can be relative or absolute percentages.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

A number of example materials are given throughout the examples of the current disclosure, it should be noted that the chemical formulas given for each of the example materials should not be construed as limiting and that the non-limiting example materials given should not be limited by a given example stoichiometry.

Lift pin constructions as disclosed herein are generally configured to comprise a lift pin that is attached to a weight element through the use of a retaining element. In an example, such a lift pin construction may contact a lift pin pad to facilitate reduced friction as the lift pin is displaced within a reaction chamber used for semiconductor fabrication processing.

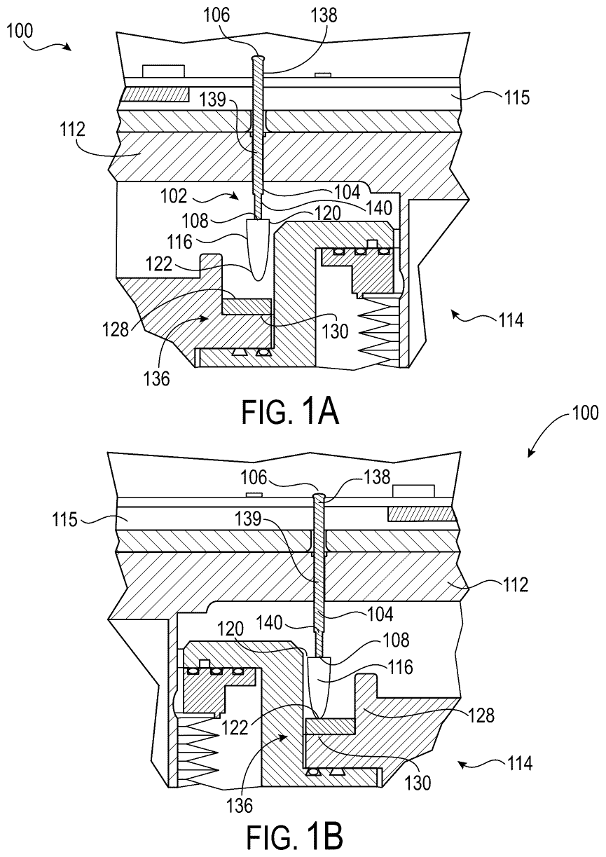

FIG. 1A illustrates a semiconductor fabrication processing apparatus 100 comprising an example weighted lift pin 102 that is disposed within the apparatus 100.

In an example, the weighted lift pin 102 comprises a lift pin that extends axially from a lift pin top end 106 to a lift pin bottom end 108, wherein in an example the lift pin top end 106 is shaped to accommodate placement of a semiconductor wafer thereon to support the same. In an example, the lift pin top end 106 may be flat. In an example, the lift pin 104 has a cylindrical shape and is sized for placement within a through hole 110 that extends axially through a portion of a susceptor 112, or the direction along the center or axis of rotation of the susceptor 112, in the semiconductor fabrication processing apparatus 100. In an example, the through hole 110 extends through a portion of the susceptor 112 that is disposed in a reaction chamber 114 of the apparatus 100. The through hole 110 may or may not include a bushing disposed therein and interposed between the lift pin 104 and the through hole 110. In an example, the through hole 110 is sized to permit free sliding axial up and down movement of the lift pin 104 therein.

The lift pin top end 106 is positioned above the susceptor 112 to accept placement of a silicon wafer thereon. The lift pin 104 extends through the through hole 110 such that the lift pin bottom end 108 is disposed below the susceptor 112. A weight element 116 is attached to the lift pin 104 below the susceptor 112 and comprises a lift pin opening disposed axially through a weight element top end 120 of the weight element 116 that extends a partial depth therein. In an example, the weighted lift pin 102 comprises a retaining element configured to securely attach the weight element 116 to the lift pin 104. In an example, the retaining element may be provided in the form of a threaded section of the lift pin adjacent the lift pin bottom end 108 and a threaded section of the weight element 116 disposed in the lift pin openings that are specially configured to be noncomplementary so as to form an interlocked threaded engagement therebetween as described in better detail below.

FIG. 1A illustrates a state of the apparatus 100 where the lift pin 104 is in an up position. In the up position, lift pin 104 is able to accommodate placement of the silicon wafer thereon and above the susceptor 112. Subsequently there can be a downward movement of the silicon wafer onto the susceptor 112 for fabrication processing. Upward movement of the susceptor relative to the lift pin 104, or to downward movement of the lift pin 104 relative to the susceptor 112 may be caused by a device configured to move the lift pin 104 separately from the susceptor 112.

FIG. 1B illustrates the apparatus 100 and the lift pin 104 as described above and illustrated in FIG. 1A except that the lift pin 104 is in a down position with the lift pin top end 106 moved axially closer to the susceptor 112. As noted above, the change in axial location of the of lift pin within the apparatus may occur by axial up or down movement of the susceptor 112 or by axial up and down movement of a device contacting a weight element bottom end 122 of the lift pin weight element 116. In an example, the lift pin 104 may have a diameter of from about 2 to 6 mm, and in a particular example has a diameter of approximately 4 mm, and may have an axial length of from about 75 to 150 mm, and in a particular example has an axial length of approximately 99 mm.

The lift pin 104 comprises three main sections: the top section 138, the base section 139, and the bottom section 140. The top section 138 includes a notch portion designed to support and laterally confine the wafer. The notch portion horizontally sweeps away from the wafer along a radius, allowing rotation to adjust lateral confinement. Lift pin 104 can be constructed from high-performance materials such as stainless steel, titanium, or other alloys. Additionally or alternatively, lift pin 104 can also be constructed of nickel, tungsten and/or ceramic, such as AlO, AlN, SiN, SiC and etc. These materials are chosen for their durability, thermal stability, and resistance to chemical corrosion. In some examples, the lift pin may be coated with a protective layer to enhance its lifespan and performance.

The weight element 116 is attached to the lift pin. The weight element 116 comprises a main body and an attachment mechanism. The main body is generally cylindrical or disk-shaped, with dimensions tailored to the specific lift pin 104 and wafer handling system. In an example, the weight element 116 is configured comprising a weight element top end 120 that is flat. In an example, the weight element top end 120 has a diameter of from about 30 to 60 mm, and in a particular example has a diameter of approximately 45 mm. In an example, the weight element 116 comprises a sleeve section that has a constant diameter that is the same as the weight element top end diameter, wherein the sleeve section extends axially from the weight element top end 120 to the weight element bottom end 122. In an example, the sleeve section has an axial length of from about 24 to 32 mm, and in a particular example of approximately 28 mm. While particular dimensions of the lift pin 104 and the different sections of the weight element 116 have been provided, it is to be understood that the dimensions of the lift pin 104 and the weight element 116 sections may vary from the examples provided herein, e.g., depending on the size or scale of the semiconductor fabrication processing apparatus, and that such variation in dimension of the lift pin and weight element 116 is intended to be within the scope of the lift pin construction as disclosed herein. In an example, the weight element bottom end 122 is configured as a curved surface, that interacts with the contacts 124, as described below. The attachment mechanism is integrated into the main body and securely attaches the weight element 116 to the lift pin 104. This may include threaded sections, clip elements, or O-ring elements, or the like or a combination thereof. The weight element 116 may be constructed from high-density materials such as tungsten, stainless steel, or other alloys. In examples, the weight element 116 may be coated with a protective layer to enhance its lifespan and performance.

In an example, the weight element 116 is configured to have a weight that is similar to existing weight elements used with existing lift pins so as to ensure the same amount of downward gravity force acts on the lift pin as disclosed herein. In an example, the weight element 116 may be formed from a structurally rigid material suitable for use in the semiconductor fabrication process environment that resists deformation, outgassing, or otherwise introduce any form of contaminants, and that is resistant of pitting, crevice corrosion, and stress corrosion cracking at the temperatures and upon exposure to chemicals encountered during semiconductor processing. In an example, the weight element is formed from a metal or metal alloy material, and in a particular example the weight element is formed from an austenitic nickel-chromium-molybdenum-tungsten alloy.

The lift pin pads 136 may be disposed below the susceptor 112 of apparatus 100. For example, the lift pin pads 136 may be affixed to the bottom surface of the reaction chamber 114. Alternatively, the lift pin pads 136 may be movable relative to the susceptor 112. For example, the lift pin pads 136 may be coupled to an actuator or the like to move the lift pin pads 136 up and down. Each lift pin pad 136 is arranged directly below and aligned with a respective lift pin. The contact 124 can be coupled with an actuator which pushes lift pin 104 up and down through the through hole 110 of a static susceptor. Each lift pin pad 136 may have a top surface with an area large enough to support the respective lift pin. The lift pin pad 136 comprises a pin pad top end and a pin pad bottom end 130, The pin pad top end interfaces with the weight element of lift pin. The lift pin pad 136 is generally circular or rectangular in shape, and dimensions tailored to the specific lift pin 104 and weight element 116. The lift pin pad 136 may be constructed from high-performance materials such as silicon carbide, alumina, or other ceramics. These materials are chosen for their durability, thermal stability, and resistance to chemical corrosion. In some designs, the pad may be coated with a protective layer to enhance its lifespan and performance.

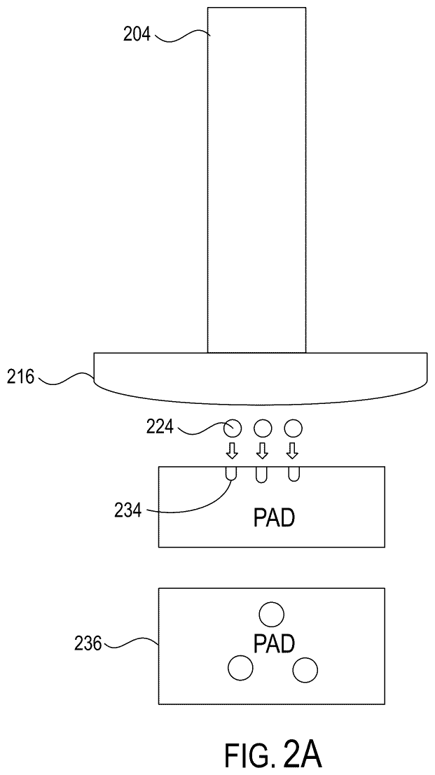

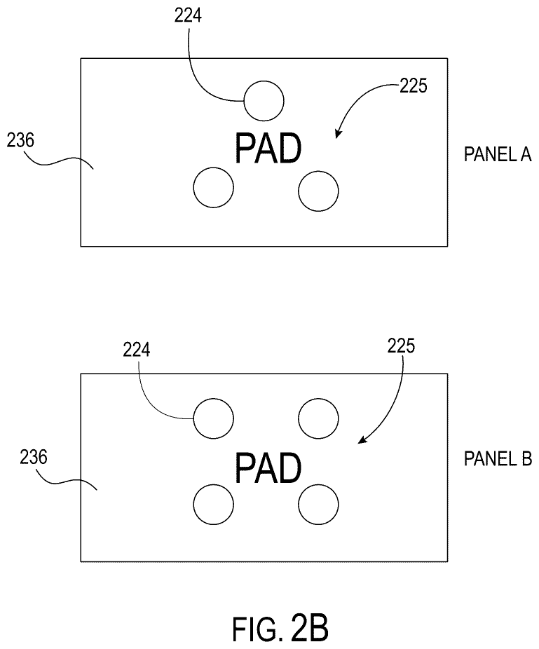

FIG. 2A illustrates an example of the lift pin 204, similar to lift pin 104 construction of FIGS. 1A and 1B with contacts 224 on a lift pin pad 236. In various example, each lift pin pad 236 may comprise a plurality of groove portions 234 disposed within the lift pin pad 236. The groove portions 234 are typically linear or curved indentations on the support surface. In examples the groove portions are in a triangular pattern on lift pin pad 236. The groove portions 234 are designed to accommodate the contacts 224 and ensure precise alignment during movement. In examples, contacts 224 are pressed fit into the groove portions 234 of the lift pin pad 236. In other examples, the contacts 224 are thermal fit, sintered or laser welded, etc. with the lift pin pad 236. The contacts 224 are designed to fit precisely into a groove portions 234, where controlled pressure is applied to create the groove portions 234. The groove portions 234 on the lift pin pad 236 are constructed from high-performance materials such as silicon carbide, alumina, or other ceramics. These materials are chosen for their durability, thermal stability, and resistance to chemical corrosion. The lift pin pad 236 itself is made from similar materials to ensure compatibility and longevity.

In examples, the material hardness of the weight element 216 is higher than the material hardness of the contacts 224. In examples, the contacts 224 are balls of a hardness that is harder than the lift pin pad 236. In examples, the frictional coefficient of the weight element and the contacts 224 may be the same. In examples where the contacts 224 are thermal fit into the lift pin pad 236, a coefficient of thermal expansion (or CTE) of the contacts 224 is higher than a CTE of the lift pin pad 236. In examples where the contacts 224 are sintered into the lift pin pad 236, and the contacts 224 and the lift pin pad 236 may be comprised of the same material. In examples the contacts 224 can be comprised of silicon nitride material. Additionally or alternatively, contacts 224 can be comprised of ceramic material, such as SiN, SiC, AlO, and/or AlN

In examples shown in FIG. 2B, one or more contacts 224 is arranged in a pattern 225 on a top surface of lift pin pad 236. The pattern 225 may define a variety of shapes such as a triangle (shown in FIG. 2B, Panel A), circle, rectangle (shown in FIG. 2B, Panel B), or the like, or a combination thereof. As a susceptor, such as susceptor 112 of FIG. 1A and FIG. 1B, exerts pressure on lift pin 204, the pattern may distribute a load of the lift pin 204 (e.g., the load may be more evenly distributed over one or more contacts 224). In an example, such distribution may reduce stress on individual contacts 124 and extend a lifespan of lift pin by reducing the risk of tipping or uneven load distribution. The spacing and alignment of balls within groove portions 134 can also minimize friction between the weight element and lift pin pad 236, which can cause undue stress on lift pin 204. A well-balanced lift pin 204 is also less likely to experience sudden failures or accidents, and allows an apparatus, such as apparatus 100 of FIGS. 1A and 1B, to operate more efficiently.

In an example, the contact pattern is triangular and the axial center of gravity (or CG) of lift pin and weight element 116 is within the triangular area enclosed and/or defined by the contacts 224. The CG of a lift pin 204 refers to the point where the mass of the lift pin 204 is evenly distributed in all directions. This is the point at which the lift pin 204 can be balanced perfectly without tipping over. A processor may move the susceptor 112 down to the wafer unloading position. When the susceptor 112 moves down, the weight elements 216 of lift pins 204 make contact with the lift pin pads 236 and the lift pins 204 lift a wafer off the surface of the susceptor 112 and re-centers the lift pin 204.

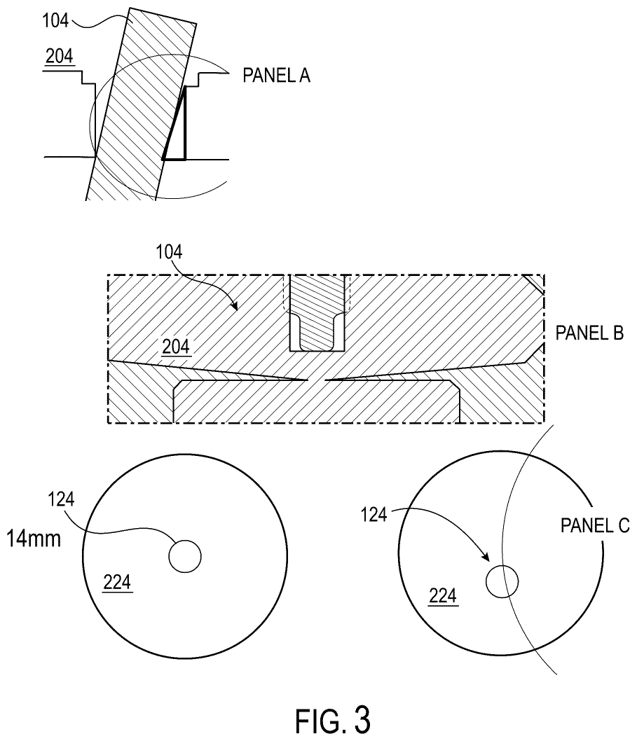

FIG. 3 illustrates an axis analysis. As described above, lift pin 104 or 204 of FIGS. 1A, 1B, 2A and 2B comprises three main sections: the top section, the base section, and the bottom section. The off-axis analysis involves setting up measurement equipment to monitor the lift pin's movement. This may include laser displacement sensors, optical encoders, or other precision measurement devices. During wafer handling operations, data is collected on the lift pin's movement. This includes tracking its vertical displacement, lateral deviations, and any rotational movements. The collected data is analyzed to identify any off-axis deviations. This involves comparing the lift pin's actual movement to its intended vertical axis. As shown in FIG. 3A, deviations can be quantified in terms of displacement, angle, and direction. FIG. 3B illustrates a lift pin with a hole between ∅3.94 and ∅4.21. In this example, the max tilt angle of FIG. 3A is 1.1°. As shown in FIG. 3C, the contacts 124 can tolerate slight misalignments of the CG, which can aid in maintaining performance in various applications. The CG will walk by ~2 mm in the extreme case for current synergies configuration, which will be the case of two points contacts 124. By contact with the contacts 124, adjustments are made to the lift pin 104 and its actuating mechanism to correct any off-axis deviations by realigning the lift pin 104, to ensure precise and stable vertical movement of the lift pin 104. By detecting and correcting any deviations, the load is distributed more evenly, reducing stress on the lift pin 104 and other components of the wafer handling system. The contacts 124 or 224 of FIGS. 1A, 1B, 2A, and 2B help maintain the accuracy and reliability of wafer handling processes.

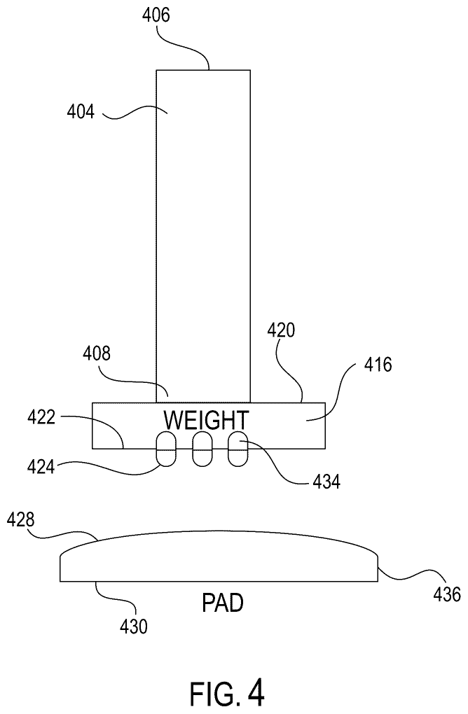

FIG. 4 is a schematic cross-sectional view of another example lift pin 404 construction as disclosed herein with contacts 424 on the weight element 416. FIG. 4 illustrates the lift pin 404, similar to lift pin 104. However, the groove portions 434 and contacts 424 are in the weight element 416 instead of the lift pin pad 436. In this example, a semiconductor fabrication processing apparatus, such as apparatus 100 of FIGS. 1A and 1B, comprises: a susceptor disposed within an interior space 115 of reaction chamber 114, wherein the susceptor comprises a plurality of through-holes in an axial direction of the susceptor, such as susceptor 112 of FIGS. 1A and 1B; and one or more lift pins 404 slidably disposed in the respective through-holes; a weight element 416 disposed along an end of the lift pin 404, wherein the weight element 416 is removably retained on the lift pin 404 by a retaining element; and one or more lift pin pads 436 disposed below the susceptor, wherein each lift pin pad 436 is aligned with one lift pin 404 from the plurality of lift pins 404, wherein each weight element 416 comprises one or more contacts 424 that are in contact with the lift pins 404, as described below.

The weight element 416 is attached to the lift pin 404. The weight element 416 comprises a main body and an attachment mechanism. The main body is generally cylindrical or disk-shaped, with dimensions tailored to the specific lift pin 404 and wafer handling system. In an example, the weight element 416 is configured comprising a weight element top end 420 that is flat. In an example, the weight element top end 420 has a diameter of from about 30 to 60 mm, and in a particular example has a diameter of approximately 45 mm. In an example, the weight element 416 comprises a sleeve section that has a constant diameter that is the same as the weight element top end 420 diameter, wherein the sleeve section extends axially from the weight element top end 420 to the weight element bottom end 422. In an example, the sleeve section has an axial length of from about 24 to 32 mm, and in a particular example of approximately 28 mm. While particular dimensions of the lift pin 404 and the different sections of the weight element 416 have been provided, it is to be understood that the dimensions of the lift pin 404 and the weight element 416 sections may vary from the examples provided herein, e.g., depending on the size or scale of the semiconductor fabrication processing apparatus 100 of FIGS. 1A and 1B, and that such variation in dimension of the lift pin 404 and weight element 416 is intended to be within the scope of the lift pin construction as disclosed herein. In an example, the weight element 416 is configured comprising a weight element bottom end 422 that is flat with groove portions 434 that accommodates contacts 424 as described below. The attachment mechanism is integrated into the main body and securely attaches the weight element 416 to the lift pin 404. This may include threaded sections, clip elements, or O-ring elements, or the like or a combination thereof. The weight element 416 may be constructed from high-density materials such as tungsten, stainless steel, or other alloys. In examples, the weight element 416 may be coated with a protective layer to enhance its lifespan and performance.

In an example, the weight element 416 is configured to have a weight that is similar to existing weight elements used with existing lift pins so as to ensure the same amount of downward gravity force acts on the lift pin as disclosed herein to permit retrofit use with existing semiconductor fabrication processing equipment, may avoid the need to implement costly and time consuming equipment modifications or changes to promote easy interchangeable installation and use of the weighted lift pins as disclosed herein. The weight requirements vary by applications, depending on factors such as the properties of process gas, chamber pressure delta on pin head and tail, lift pin roughness etc. In an example, the weight element 416 may be formed from a structurally rigid material suitable for use in the semiconductor fabrication process environment that resists deformation, outgassing, or otherwise introducing any form of contaminants, and that is resistant of pitting, crevice corrosion, and/or stress corrosion cracking at the temperatures and upon exposure to chemicals encountered during semiconductor processing. In an example, the weight element 416 is formed from a metal or metal alloy material, and in a particular example the weight element 416 is formed from an austenitic nickel-chromium-molybdenum-tungsten alloy.

The lift pin pads 436 may be disposed below the susceptor 112 of apparatus 100 of FIGS. 1A and 1B and are similar to lift pin pads 136. However, lift pin pads 436 may not comprise a plurality of groove portions 434 disposed within lift pin pad 436. For example, the lift pin pads 436 may be affixed to the bottom surface of the reaction chamber 114. Alternatively, the lift pin pads 436 may be movable relative to the susceptor 112. For example, the lift pin pads 436 may be coupled to an actuator or the like to move the lift pin pads 436 up and down. Each lift pin pad 436 is arranged directly below and aligned with a respective lift pin 404. Each lift pin pad 436 may have a top surface with an area large enough to support the respective lift pin 404. The lift pin pad 436 comprises a pin pad top end 428 and a pin pad bottom end 430, The pin pad top end 428 interfaces with the weight element 416 of lift pin 404. The lift pin pad 436 is generally circular or rectangular in shape, and dimensions tailored to the specific lift pin 404 and weight element 416. The lift pin pad 436 may be constructed from high-performance materials such as silicon carbide, alumina, or other ceramics. These materials are chosen for their durability, thermal stability, and resistance to chemical corrosion. In some designs, the pad may be coated with a protective layer to enhance its lifespan and performance.

In various examples, each weight element 416 may comprise a plurality of groove portions 434 disposed within the weight element 416. The groove portions 434 are similar to groove portions 134 and are typically linear or curved indentations on the bottom surface. In examples the groove portions 434 are in a triangular pattern on weight element 416. The groove portions 434 are designed to accommodate the contacts 424 and ensure precise alignment during movement. In examples, contacts 424 are pressed fit into the groove portions 434 of the weight element 416. In other examples, the contacts 424 are thermal fit, sintered or laser welded, etc. with the lift pin pad 436. In examples, the material hardness of the lift pin pad 436 is higher than the material hardness of the contacts 424. In examples, the contacts 424 are balls of a hardness that is harder than the weight element 416. In examples, the frictional coefficient of the lift pin pad 436 and the contacts 424 are the same. In examples, where the contacts 424 are thermal fit into the weight element 416, a CTE of the contacts 424 may be higher than a CTE of the weight element 416. In examples where the contacts 424 are sintered into the weight element 416, the contacts 424 and the weight element 416 may be comprised of the same material.

As a susceptor, such as the susceptor 112 of FIGS. 1A and 1B exerts pressure on lift pin 404, the pattern can help distribute load of the lift pin 404 evenly, reducing stress on individual contacts 424 and extending the lifespan. The spacing and alignment of balls within groove portions 434 can also minimize friction between the weight element 416 and lift pin pad 436, allowing for smoother and more efficient operation of the lift pin 404. A processor may move the susceptor 112 down to the wafer unloading position. In an example, the axial cent when in the down position, the axial center of gravity or CG of lift pin 404 and weight element 116 may be within the triangular area enclosed by the contacts 424. When the susceptor moves down, the weight elements 416 of lift pins 404 make contact with the lift pin pads 436 and the lift pins lift a wafer off the surface of the susceptor 112 and re-centers the lift pin 404.

Lift pins as disclosed herein, such as lift pin 104, lift pin 204, and lift pin 404, may be made from structural materials that are chemically resistant and thermally stable so as to resist degradation and/or outgas or otherwise generate unwanted particle matter when subjected to chemicals and the elevated temperatures associated with semiconductor fabrication processing. In an example, lift pins as disclosed herein may be formed from metals or metal alloys, and in a particular example may be formed from titanium or titanium alloy. In such an example, it may be desired to provide a coating or film on the lift pin for the purpose of providing desired enhanced surface properties such as wear resistance, chemical resistance, and the like. In an example where the lift pin is formed from titanium, it may be desired to provide a coating made from titanium nitride (TiN).

Lift pins as used both with weighted lift pin constructions as disclosed herein and as used in other lift pin configurations and construction may be formed in a manner that provides a reduced degree of surface friction or an increased degree of surface lubricity. In an example, it is desired that lift pins move freely within through holes during operation and do not stick or otherwise not smoothly travel up or down. Greases and other types of conventional lubricants are unsuited for use with lift pins used in semiconductor fabrication processing because of potential contamination in the reaction chamber. In an example, it is desired that the lift pins have a graphite-like surface structure provided by surface treatment that may be only a few micrometers thick. In an example, to achieve this purpose, it may be desired to form lift pins from molybdenum. In an example, the surface of the molybdenum lift pin may be treated to provide or form a molybdenum disulfide film or layer thereon, which operates to provide a lift pin surface having a reduced degree of friction and an improved degree of surface lubricity to ensure desired smooth operation of the lift pins while minimizing or avoiding possible contamination. In an example, the molybdenum disulfide coating or film may have a thickness of from about 0.1 to 10 micrometers. While particular materials have been disclosed for purposes of forming lift pins having reduced properties of surface friction, it is to be understood that other types of materials may be used to form and coat lift pins that operate to provide the same or similar function, and that all such materials are intended to be within the scope of lift pins having reduced surface friction as disclosed herein.

Although but a few example examples of weighted lift pins as used in semiconductor fabrication processing have been disclosed in detail above, those skilled in the art will readily appreciate that many modifications are possible in the example examples without materially departing from the intent and purpose of the example systems and method as disclosed herein. For example, while weight elements having a particular outer configuration have been disclosed it is to be understood that weight elements having different outer configurations that may be attached to the lift pin in the manner described are intended to be within the scope of weighted lift pins as disclosed herein. Accordingly, all such modifications of weighted lift pins are intended to be included within the scope of this disclosure as defined in the following claims.

For purposes of summarizing the invention and the advantages achieved over the prior art, certain objects and advantages of the invention have been described herein above. Of course, it is to be understood that not necessarily all such objects or advantages may be achieved in accordance with any particular example of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these examples are intended to be within the scope of the invention herein disclosed. These and other examples will become readily apparent to those skilled in the art from the following detailed description of certain examples having reference to the attached figures, the invention not being limited to any particular example(s) disclosed.

What is claimed is:

1. A semiconductor fabrication processing apparatus comprising:
a susceptor disposed within an interior space of a reaction chamber, wherein the susceptor comprises a through-hole disposed in an axial direction;
a lift pin slidably disposed in the through-hole;
a weight element coupled to an end of the lift pin, wherein the weight element is removably retained on the lift pin by a retaining element; and
a pin pad disposed below the susceptor, wherein the pin pad is aligned with the lift pin, wherein the pin pad comprises one or more contacts that contact the weight element.

2. The semiconductor fabrication processing apparatus of claim 1, wherein an axial center of gravity of the lift pin is aligned with the pin pad within a triangular area defined by the one or more contacts.

3. The semiconductor fabrication processing apparatus of claim 1, wherein the one or more contacts are pressed fit, thermal fit, sintered or laser welded with the pin pad.

4. The semiconductor fabrication processing apparatus of claim 1, wherein a first frictional coefficient of the weight element and a second frictional coefficient of the one or more contacts are the same.

5. The semiconductor fabrication processing apparatus of claim 1, wherein the one or more contacts are pressed fit into the pin pad,
wherein a first material hardness of the weight element is higher than a second material hardness of the one or more contacts, and
wherein the second material hardness is higher than a third material hardness of the pin pad.

6. The semiconductor fabrication processing apparatus of claim 1, wherein the one or more contacts are thermal fit into the pin pad, and wherein a first coefficient of thermal expansion (CTE) of the one or more contacts is higher than a second CTE of the pin pad.

7. The semiconductor fabrication processing apparatus of claim 1, wherein the one or more contacts are sintered into the pin pad, and wherein the one or more contacts and the pin pad are comprised of the same material.

8. The semiconductor fabrication processing apparatus of claim 1, wherein the one or more contacts are comprised of silicon nitride material.

9. A semiconductor fabrication processing apparatus comprising:
a susceptor disposed within an interior space of a reaction chamber, wherein the susceptor comprises a through-hole disposed in an axial direction of the susceptor;
a lift pin slidably disposed in the through-holes;
a weight element coupled to an end of the lift pin, wherein the weight element is removably retained on the lift pin by a retaining element; and
a pin pad disposed below the susceptor, wherein the pin pad is aligned with the lift pin,
wherein the weight element comprises one or more contacts that contact the lift pin.

10. The semiconductor fabrication processing apparatus of claim 9, wherein an axial center of gravity of the pin is aligned with the weight element within a triangular area and defined by the one or more contacts.

11. The semiconductor fabrication processing apparatus of claim 9, wherein the one or more contacts are pressed fit, thermal fit, sintered or laser welded with the weight element.

12. The semiconductor fabrication processing apparatus of claim 9, wherein a first frictional coefficient of the pin pad and a second frictional coefficient of the one or more contacts are the same.

13. The semiconductor fabrication processing apparatus of claim 9, wherein the one or more contacts are pressed to fit into the weight element,
wherein a first material hardness of the pin pad is higher than a second material hardness of the contact, and
wherein the second material hardness is higher than a third material hardness of the weight element.

14. The semiconductor fabrication processing apparatus of claim 9, wherein the one or more contacts are thermal fit into the weight element, and wherein a first coefficient of thermal expansion CTE of the one or more contacts is higher than a second CTE of the weight element.

15. The semiconductor fabrication processing apparatus of claim 9, wherein the one or more contacts are sintered into the weight element, and wherein the one or more contacts and the weight element are comprised of the same material.

16. A semiconductor fabrication processing apparatus comprising:
a susceptor disposed within an interior space of a reaction chamber, wherein the susceptor comprises through-holes disposed in an axial direction of the susceptor;
a lift pin slidably disposed in the respective through-holes;
a pin pad disposed below the susceptor, wherein the pin pad is aligned with the lift pin; and
a weight element coupled to an end of the lift pin, wherein the weight element is removably retained on the lift pin by a retaining element,
wherein the lift pin comprises one or more contacts that contact the weight element.

17. The semiconductor fabrication processing apparatus of claim 16, wherein the one or more contacts are pressed fit, thermal fit, sintered or laser welded with the lift pin.

18. The semiconductor fabrication processing apparatus of claim 16, wherein a first frictional coefficient of the weight element and a second frictional coefficient of the one or more contacts are the same.

19. The semiconductor fabrication processing apparatus of claim 9, wherein the one or more contacts are pressed fit into the lift pin,
wherein a first material hardness of the weight element is higher than a second material hardness of the one or more contacts, and
wherein the second material hardness is higher than a third material hardness of the lift pin.

20. The semiconductor fabrication processing apparatus of claim 1, wherein the one or more contacts are thermal fit into the lift pin, and wherein a first coefficient of thermal expansion (CTE) of the one or more contacts is higher than a second CTE of the lift pin.
